(19) United States
(12) Patent Application Publication
(10) Pub. No.: US 2024/0282658 A1
(43) Pub. Date: Aug. 22, 2024

(54) INTEGRATED CIRCUIT DIES WITH THERMALLY CONDUCTING SOLDER PERIMETER

(71) Applicant: INTERNATIONAL BUSINESS MACHINES CORPORATION, ARMONK, NY (US)

(72) Inventors: John Knickerbocker, Monroe, NY (US); Mukta Ghate Farooq, HOPEWELL JCT, NY (US); Keiji Matsumoto, Yokohama-shi (JP)

(21) Appl. No.: 18/169,998

(22) Filed: Feb. 16, 2023

(51) Int. Cl. H01L 23/31; H01L 21/56; H01L 23/00; H01L 23/29; H01L 23/367

(52) U.S. Cl. CPC H01L 23/3185; H01L 21/561; H01L 23/29; H01L 23/291; H01L 23/3192; H01L 23/3675; H01L 24/16; H01L 24/27; H01L 24/29; H01L 24/32; H01L 24/33; H01L 24/95; H01L 2224/16225; H01L 2224/2732; H01L 2224/2741; H01L 2224/2745; H01L 2224/27462; H01L 2224/2783; H01L 2224/29083; H01L 2224/29111; H01L 2224/29139; H01L 2224/29147; H01L 2224/29181; H01L 2224/29186; H01L 2224/2919; H01L 2224/32153; H01L 2224/32221; H01L 2224/33183; H01L 2224/95; H01L 2924/0132; H01L 2924/0133; H01L 2924/04953; H01L 2924/07025

(57) ABSTRACT

A semiconductor integrated circuit device includes a first back-end-of-line region coupled to a first side of a front-end-of-line region, a second back-end-of-line region coupled to a second side of the front-end-of-line region, and a thermally conducting solder at least partially surrounding a perimeter of the front-end-of-line region, the first back-end-of-line region and the second back-end-of-line region.

### BACKGROUND

The present application relates to semiconductors, and more specifically, to techniques for forming semiconductor structures. Semiconductors and integrated circuit dies have become ubiquitous within many products, particularly as they continue to decrease in cost and size. There is a continued desire to reduce the size of structural features and/or to provide a greater amount of structural features for a given die size. Miniaturization, in general, allows for increased performance at lower power levels and lower cost. Present technology is at or approaching atomic level scaling of certain micro-devices such as logic gates, field-effect transistors (FETs), and capacitors. As the electricity required to a relatively increased number of micro-devices within integrated circuit die has increased, so too has the need to remove heat, the byproduct of the electricity, from integrated circuit die.

### SUMMARY

Embodiments of the disclosure provide techniques for forming integrated circuit dies with thermally conducting solder perimeter. In an embodiment, a packaged semiconductor integrated circuit device is presented. The package semiconductor integrated circuit device includes a die and a cover. The die includes a first back-end-of-line region coupled to a first side of a front-end-of-line region, a second back-end-of-line region coupled to a second side of the front-end-of-line region, and a thermally conducting solder at least partially surrounding perimeter sidewalls of the front-end-of-line region, the first back-end-of-line region, and the second back-end-of-line region. The cover conceals the die and includes a lateral heatsink portion in conduction connection with a sidewall of the thermally conducting solder.

The thermally conducting solder is advantageously utilized in the packaged integrated circuit device because of a relatively lower elastic modulus of the solder metal material, compared to other metals (such as Copper) that have relatively high heat transfer coefficients (i.e., metals that are good thermal conductors with relatively higher elastic modulus). Because of the relatively lower elastic modulus of thermally conductive solder, the thermally conducting solder relatively relaxes under thermal excursions, i.e., when heat is being removed from the operating die. Further, the ability of the thermally conducting solder to relax and/or expand, enables an increased, repeatable, reliable conduction contact with the lateral heatsink portion of the cover, compared to other metals (such as Copper) that are good conductors of heat. Therefore, a relatively increased conduction of heat away from the operating die and into cover may be enabled because of the elastic or deformable nature of the thermally conductive solder.

In one example, the first back-end-of-line region provides signal routing for one or more active devices in the front-end-of-line region, and the second back-end-of-line region provides a power delivery structure for the one or more active devices in the front-end-of-line region.

In one example, the packaged semiconductor integrated circuit device further includes a carrier and a plurality of solder balls that connect the carrier and the second back-end-of-line region. In one example, a reflow temperature of the thermally conducting solder is higher than a reflow temperature of the plurality of solder balls. The reflow temperature of the thermally conducting solder may be higher than the reflow temperature of the plurality of solder balls to advantageously allow for the disconnection of the package die without reflowing the thermally conducting solder around the perimeter of the die.

In one example, an oxide layer is between the thermally conducting solder and just the front-end-of-line region. In another example, the oxide layer is between (i) the thermally conducting material and the entire (ii) the front-end-of-line region, the first back-end-of-line region and the second back-end-of-line region.

In one example, the lateral heatsink portion is in direct conduction connection with the sidewall of the thermally conducting solder. In one example, a thermal interface material is between the lateral heatsink portion and the sidewall of the thermally conducting solder. In one example, a width of the thermally conducting solder is 50 um or more.

In an embodiment, a semiconductor integrated circuit device fabrication method is presented. The method includes initially dicing a plurality of dies from a wafer, aligning a mask with the wafer, depositing a barrier layer material through the mask upon perimeter sidewalls of each of the plurality of dies, depositing thermally conductive solder upon the barrier layer to rejoin the plurality of dies, and re-dicing the plurality of dies while retaining the thermally conductive solder upon respective perimeter sidewalls of each of the plurality of dies.

The thermal conducting solder retained upon respective perimeter sidewalls of each of the plurality of dies advantageously provides a cooling path for the diced and operating dies. Thermal modeling demonstrates that a perimeter of thermally conducting solder surrounding the integrated circuit die can provide significant reduction in the overall maximum temperature of the integrated circuit die (e.g., such as reducing the maximum die temperature by one degree Celsius (° C.) or greater).

In an embodiment, a semiconductor integrated circuit device is presented. A semiconductor integrated circuit device includes a first back-end-of-line region coupled to a first side of a front-end-of-line region, a second back-end-of-line region coupled to a second side of the front-end-of-line region, and a thermally conducting solder at least partially surrounding perimeter sidewalls of the front-end-of-line region, the first back-end-of-line region, and the second back-end-of-line region.

The thermal conducting solder advantageously provides a cooling path for the semiconductor integrated circuit device, such as a diced and operating die. Thermal modeling demonstrates that a perimeter of thermally conducting solder can provide significant reduction in the overall maximum temperature of the semiconductor integrated circuit device (e.g., such as reducing the maximum the semiconductor integrated circuit device temperature by one degree Celsius (° C.) or greater).

These and other features and advantages of embodiments described herein will become more apparent from the accompanying drawings and the following detailed description.

### BRIEF DESCRIPTION OF THE DRAWINGS

FIG. 1 depicts a wafer that may utilize one or more embodiments of the disclosure.

FIG. 2 depicts a packaged integrated circuit device that may utilize one or more embodiments of the disclosure.

FIG. 3 depicts a cross-section view of an integrated circuit device that includes a die with a perimeter of thermally conducting solder, according to one or more embodiments of the disclosure.

FIGS. 4A and 4B depict cross-section views of an integrated circuit device that includes a die with a perimeter of thermally conducting solder, according to one or more embodiments of the disclosure.

FIG. 4C shows a close-up view of a portion of an exemplary perimeter of thermally conducting solder, according to one or more embodiments of the disclosure.

FIG. 5 and FIG. 6 depict orthogonal cross-section views of an integrated circuit device that includes a die with a perimeter of thermally conducting solder and with one or more lateral heatsinks thereupon, according to one or more embodiments of the disclosure.

FIG. 7A and FIG. 7B depicts cross-section views of a packaged integrated circuit device that includes a die with a perimeter of thermally conducting solder, according to one or more embodiments of the disclosure.

FIG. 8A through FIG. 8F depict a method of fabricating a die with a perimeter of thermally conducting solder, according to one or more embodiments of the disclosure.

FIG. 9 depict a method of fabricating a die with a perimeter of thermally conducting solder, according to one or more embodiments of the disclosure.

FIG. 10 depicts a table characterizing reduction in maximum die temperature as a function of a width of a perimeter of thermally conducting solder surrounding the die, according to an embodiment of the disclosure.

FIG. 11 depicts a table characterizing reduction in maximum die temperature as a function a presence of lateral heatsink(s) that are thermally connected to the perimeter of thermally conducting solder that surrounds the die, according to an embodiment of the disclosure.

### DETAILED DESCRIPTION

Illustrative embodiments of the disclosure may be described herein in the context of illustrative methods for forming integrated circuit dies with thermally conducting perimeter solder, along with illustrative apparatus, systems and devices formed using such methods. However, it is to be understood that embodiments of the disclosure are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

With continuous scaling, more and more devices (e.g., transistors) are packed into integrated circuit dies (e.g., into one or more 100-millimeter (mm)² dies). To provide desired functionality, the devices must be interconnected through wiring and routing. With an increased number of devices in an integrated circuit, more and more wiring and routing resources are required to precisely connect the integrated circuit as desired for a particular use case. Thus, for example, more and more metal layers may be needed to connect all of the devices in an integrated circuit.

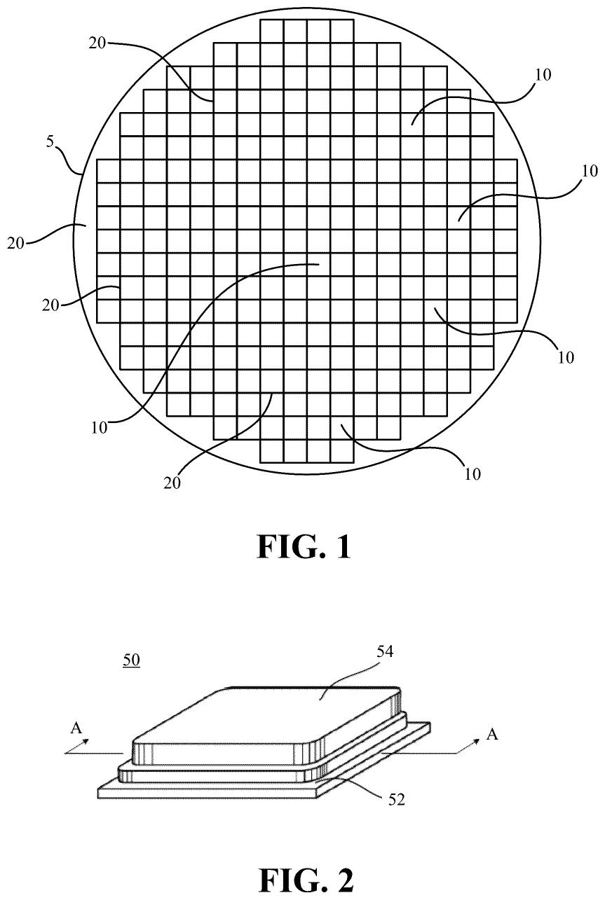

Referring to FIG. 1, integrated circuit dies may be fabricated as a part of a wafer 5 which may undergo front-end-of-line (FEOL) processing for fabricating devices (e.g., transistors, capacitors, resistors, etc.) on the wafer 5 and BEOL processing for interconnecting such devices on the wafer 5. More particularly, BEOL processes are typically focused on forming metal interconnects between the different devices of an integrated circuit, whereas the fabrication of the different devices that make up the integrated circuit is typically done during FEOL processing.

In FEOL processing, devices such as complementary metal-oxide-semiconductor (CMOS) field-effect transistors (FET) devices, nanostructure (FETs), or the like, are formed by a series of steps. For example, masking layers (e.g., photolithographic masks) may be used to form patterns on the wafer 5. Such masking layers may be used to control or define specific regions where material is to be etched or removed, as well as to control or define specific regions where material is to be formed (e.g., through deposition, growth, etc.). In some cases, materials may be blanket deposited, followed by patterning of one or more masking layers to remove previously deposited materials in some areas while leaving the previously deposited material in other areas.

In BEOL processing, fabrication of an integrated circuit continues by forming interconnects through one or more layers of wiring and dielectric passivation layers over active devices in a FEOL region formed during the FEOL processing. Interconnections or interconnects may include metallic structures that are formed in multiple levels of interlayer dielectric (TLD) layers for electrically connecting the various devices in the FEOL region. Following FEOL and BEOL processing, the wafer 5 may be separated or divided into multiple integrated circuit (IC) dies by dicing or other suitable techniques. In some cases, BEOL regions may be formed on both sides (e.g., “front” and “back” sides) of a FEOL region, improving routing resources.

An integrated circuit die may include an active device region 10 (e.g., a FEOL region with various active devices), along with a first BEOL region on a back side of the active device region 10 and a second BEOL region on a front side of the active device region 10. Neighboring active device regions 10 may be separated by boundary region 20, such as a crack stop region, kerf, or the like. In other words, an active device region 10 of one die may be separated from the respective active device region 10 of a separate die boundary region 20.

The first BEOL region may include metal layers for power delivery from the back side of the integrated circuit die providing a back side power delivery network (BSPDN), with the first BEOL region being on a carrier package side of the integrated circuit die. The second BEOL region may be on a front side of the active device region 10 and may include metal layers for signal routing from the front side of the integrated circuit die. In some cases, a heat sink is attached to the second BEOL region for cooling of the integrated circuit die. Although in some cases the first BEOL region is used for power delivery while the second BEOL region is used for signal routing, it should be appreciated that in other embodiments this may vary, including where one or both of the first and second BEOL regions include metal layers for both power and signal routing. In an example, only active device regions 10 have one or both of the first and second BEOL regions that include the metal layers for both power and signal routing while the boundary region 20 does not include metal layers for both power and signal routing.

Various structures described herein may be implemented in integrated circuits. The resulting integrated circuit dies can be distributed by the fabricator in raw wafer 5 form (that is, as a single wafer 5 that has multiple unpackaged dies, as depicted in FIG. 1), as a bare integrated circuit die, or in a packaged form. In the latter case, as depicted in FIG. 2, a die is mounted in a single die package. The single die package or multiple die package may be interchangeably referred herein generically as package 50. Package 50 may include the die(s), carrier 52, and cover 54, and/or the like. The carrier 52 may include leads that may be affixed to a motherboard or other higher level carrier. In any case, the die, the package, or the like, may then be integrated with other dies, discrete circuit elements, and/or other signal processing devices as part of either: (a) an intermediate product, such as a motherboard, or (b) an end product. The end product can be any product that includes integrated circuit dies, ranging from toys and other low-end applications to advanced computer products having a display, a keyboard or other input device, and a central processor.

In some embodiments, a process flow includes building a die with a first (e.g., “back side”) BEOL region including a BSPDN structure. A FEOL region with active devices is formed over the first BEOL region, followed by a second BEOL region over the FEOL region. In some embodiments, another process flow includes building a die with a FEOL region with active devices therein, forming a first BEOL region upon a front side of the FEOL region, flipping the structure and building a second BEOL region upon a backside of the FEOL region. The die is further fabricated with a thermal heat transfer solder structure therearound to create “chimneys” of thermally conductive solder for heat transfer away from an operating or powered die.

In some embodiments, an integrated circuit die includes a diced die with a thermally conducting solder formed around at least a portion of the perimeter of the diced die. The width of the perimeter of the thermally conducting solder may have a thickness of 100 micrometers (μm) or more. The thermally conducting solder may be a lead-free solder (e.g., SnAgCu (such as Sn-3.0Ag-0.5Cu), SnCu (such as Sn-0.75Cu), SnAg (Sn-1.8Ag), or the like.)

The structures described herein advantageously place a thermal conducting solder between active device regions 10 and a cooling path for the diced and powered and operating die. The additional thermal conducting solder may be in the form of a perimeter of thermally conducting solder surrounding the integrated circuit die. Thermal modeling demonstrates that a perimeter of thermally conducting solder surrounding the integrated circuit die can provide significant reduction in the overall maximum temperature of the integrated circuit die (e.g., such as reducing the maximum die temperature by one degree Celsius (° C.) or greater). The thermal conducting solder described herein thus provides significant value for various integrated circuit dies, where even a single degree temperature change is considered impactful.

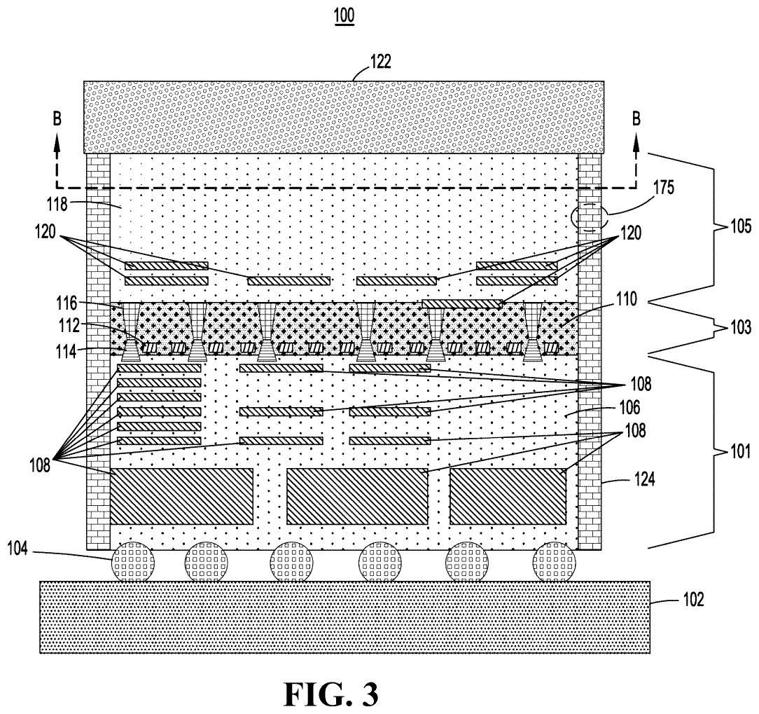

FIG. 3 depicts a cross-section view of an integrated circuit device 100 that includes an integrated circuit die, which may also be referred to herein as simply die, with a perimeter of thermally conducting solder 124, according to one or more embodiments of the disclosure. The die includes a first BEOL region 101, a FEOL region 103, and a second BEOL region 105.

The integrated circuit device 100 may further include a packaging substrate 102 (e.g., a laminate, carrier 52, or the like) with solder bumps 104 connecting the packaging substrate 102 to the first BEOL region 101. Here, the first BEOL region 101 includes one or more interlayer dielectric (ILD) layer(s) 106 with various metal line features 108 formed therein, where the metal line features 108 include BEOL wiring which may be used for a BSPDN structure to distribute power to the integrated circuit device 100. The first BEOL region 101 may have a thickness in the range of 1 to 10 μm.

The first BEOL region 101 connects to the FEOL region 103 across a backside interface. The FEOL region 103 includes one or more semiconductor layer(s) 110 (e.g., formed of silicon (Si) or another suitable semiconductor materials) in which active devices 112 are formed. The FEOL region 103 may also include vias 114 and 116. The vias 114 interconnect the active devices 112 of the FEOL region 103 with the BSPDN of the first BEOL region 101. The vias 116 interconnect the active devices 112 of the FEOL region 103 to enable signal routing in the second BEOL region 105.

The first BEOL region 101 connects to the of FEOL region 103 across a frontside interface. The second BEOL region 105 includes one or more ILD layer(s) 118 with various metal line features 120 formed therein. The metal line features 120 include BEOL wiring which may be used for signal routing in the integrated circuit device 100. A topside heatsink 122 may be connected over the second BEOL region 105.

The thermally conducting solder 124 surrounds the side or perimeter of the die, providing for enhanced thermal conduction for cooling of the powered and operating die, as the ILD layers 106 and 118 are relatively poor thermal conductors. For example, the ILD layers 106 and 118 may be formed of dielectric materials such as silicon oxide (SiO), hydrogenated silicon carbon oxide (SiCOH), SiCH, SiCNH, or other types of silicon based low-k dielectrics (e.g., k less than about 4.0), porous dielectrics, or ULK (ultra-low-k) dielectric materials (with k less than about 2.5).

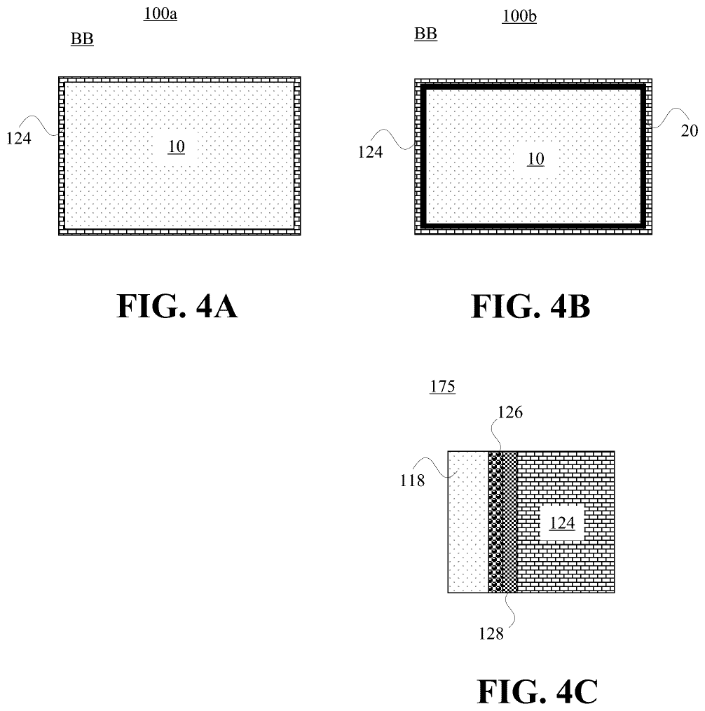

FIG. 4A and FIG. 4B depict cross-section views of integrated circuit device 100 that includes the die with the perimeter of thermally conducting solder 124, according to one or more embodiments of the disclosure. FIG. 4A depicts integrated circuit device 100a thermally conducting solder 124 surrounding a side perimeter of the active region 10 of the diced die, with a solder 124 top surface that is coplanar with a top surface of the dice die, and with a solder 124 bottom surface that is coplanar with a bottom surface of the dice die. FIG. 4B depicts integrated circuit device 100b thermally conducting solder 124 surrounding a side perimeter of the active region 10 of the diced die, with a solder 124 top surface that is coplanar with a top surface of the dice die, and with a solder 124 bottom surface that is coplanar with a bottom surface of the dice die. For example, the thermally conducting solder 124 may surround a side perimeter of the crack stop or kerf perimeter of the diced die.

In some examples, the thermally conducting solder 124 may only partially surround the perimeter of the diced die (e.g., it may be formed surrounding less than all four sides of the diced die, on portions but not the entirety of each of the four sides of the diced die, etc.).

The thermally conducting solder 124 increases the overall perimeter of the diced die by the creation of “chimneys” of the thermally conducting solder for heat dissipation. The thermally conducting solder 124 chimney may not interfere with the design of the primary die (e.g., the thermally conducting solder 124 chimney may not interfere with active region 10 which may include as transistors and other logic devices that are within the FEOL region 103).

Thermal modeling demonstrates the amount of heat dissipation which can occur within the thermally conducting solder 124, and thus how much effective temperature reduction is created. For thermal modeling, heat is set at the bottom surface of the first BEOL region 101, and a heat transfer coefficient of 20000 Watts per square meter Kelvin (W/m²K) is set at the top surface (e.g., which may be achieved through water cooling or some other type of heatsink). This is compared with a conventional structure that does not include the thermally conducting solder 124.

For simulation, a 10000 μm by 10000 μm square die structure is considered, with a thin BEOL region of 10 μm and a thick silicon (Si) region of 775 μm. FIG. 10 shows a table, showing various perimeter widths of the thermally conducting solder 124 and the resulting maximum die temperature. As shown, increasing the width of the perimeter of the thermally conducting solder 124 from 0 to 1000 μm results in a reduction in the maximum die temperature of approximately one degree Celsius. It can thus be seen that, depending on the target maximum die temperature, the perimeter width of the thermally conducting solder 124 may be tuned as needed.

FIG. 4C shows a close-up view 175 of a portion of a thermally conducting perimeter region of the die, which includes a passivation layer 126, a barrier layer 128, and a thermally conducting solder 124. The passivation layer 126 may include one or more passivation layers consisting of inorganic (e.g., nitride, oxide, etc.) and/or organic (e.g., polyimide, etc.) layers. The barrier layer 128 may be deposited upon the passivation layer 126. The barrier layer 128 allows for adhesion of the solder 124 to the passivation layer 126. The passivation layer 126 and the barrier layer 128 may be a continuous respective layer(s) around the perimeter of the die, like the solder 124 depicted in FIG. 4A. Following barrier layer 128, solder 124 may be deposited upon the barrier layer 126. Evaporation and electroplating may be used to deposit solder 124. Other methods include screen printing, solder jetting, or the like. In an example, the material of solder 124 may have a higher reflow temperature relative to the material of solder bumps 104 to enable reflow of solder bumps 104 while limiting the reflow of solder 124.

The oxide layer 126 may have a thickness in the range of 0.1 to 1 μm. The barrier layer 128 may be formed of tantalum (Ta), tantalum nitride (TaN) or another suitable material, and may have a thickness in the range of 0.1 to 1 μm. The solder 124 may have a thickness which varies as needed to achieve a desired target maximum die temperature as described in further detail below.

It should be noted that the oxide layer 126, in some cases, is optional for at least portions of the structure. For example, the oxide layer 126 may be needed in the FEOL region 103 to prevent shorting of the active devices 112. The oxide layer 126 may not be present in the first BEOL region 101 and the second BEOL region 105.

In an example, the barrier layer 128 and the thermally conducting solder 124 may be formed upon the boundary region 20, when the boundary region 20 forms the perimeter of the diced die. The crack stop region may include a metal material which is used to prevent cracking while dicing a wafer to form diced die.

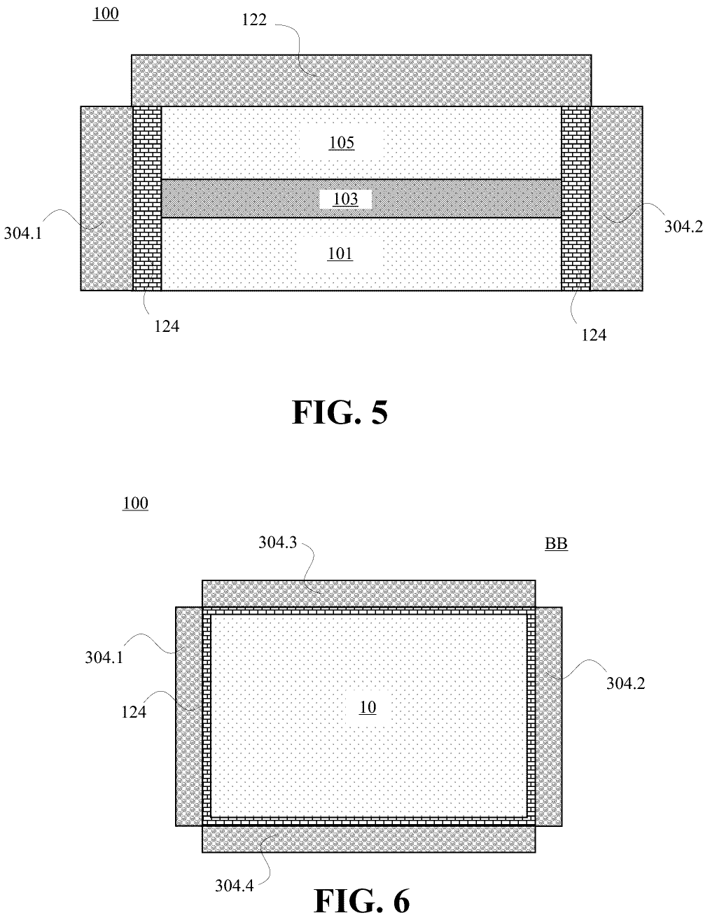

FIG. 5 and FIG. 6 depict orthogonal cross-section views of integrated circuit device 100 that includes the die with the perimeter of thermally conducting solder 124 and further includes one or more lateral heatsinks 304 upon the thermally conducting solder 124, according to one or more embodiments of the disclosure. Like topside heatsink 122, lateral heatsink 304 may be an active or passive heat exchanger that transfers the heat generated by the powered and operational die to a fluid medium, often air or a liquid coolant, where it is dissipated away from the powered and operational die, thereby allowing regulation of the powered and operational die temperature. Lateral heatsink(s) 304 may be in direct or indirect conduction connection with one or more respective sidewalls of thermally conducting solder 124. There may be one lateral heatsink 304 per respective sidewall or side surface of thermally conducting solder 124. For example, and as depicted in FIG. 6, lateral heatsink 304.1 may be in conduction connection with a left sidewall of thermally conducting solder 124, lateral heatsink 304.2 may be in conduction connection with a right sidewall of thermally conducting solder 124, lateral heatsink 304.3 may be in conduction connection with a rear sidewall of thermally conducting solder 124, and lateral heatsink 304.4 may be in conduction connection with a front sidewall of thermally conducting solder 124.

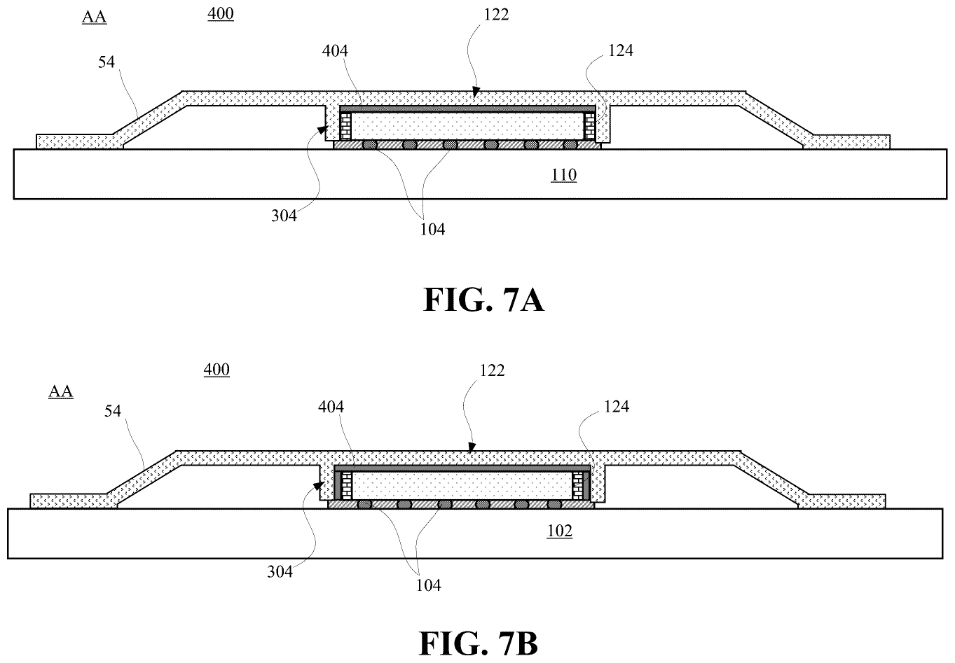

FIG. 7A and FIG. 7B depicts cross-section views of a packaged integrated circuit device 400 that includes the die with the perimeter of thermally conducting solder 124, according to one or more embodiments of the disclosure. In the depicted examples, topside heatsink 122 and/or lateral heatsink(s) 304 may be embodied by, provided by, integral with, etc., a lateral heatsink portion of cover 54. The lateral heatsink 304 portion of cover 54 may extend vertically downward from an underside of the cover. The lateral heatsink 304 portion may be chimney extending vertically downward from the underside of the cover 54 with associated dimensions required to be in conduction contact with the thermally conductive solder 124 of the die.

In an example, depicted in FIG. 7A, a thermal interface material 404 may exist between the upper surface of the die and the topside heatsink 122. In this example, therefore, topside heatsink 122 may be in indirect conduction connection with the die by way of the thermal interface material 404 instance(s). In an example, depicted in FIG. 7B, thermal interface material 404 may exist between the upper surface of the die and the topside heatsink 122 and between the side surface(s) of thermally conducting solder 124 and lateral heatsink(s) 304. In this example, therefore, topside heatsink 122 may be in indirect conduction connection with the die by way of a thermal interface material 404 instance and/or lateral heatsink 304 may be in indirect conduction connection with the die by way of the same or different thermal interface material 404 instance.

Thermally conducting solder 124 is advantageously utilized in packaged integrated circuit device 400 because of a relatively lower elastic modulus of the solder metal material, compared to other metals (such as Copper) that have relatively high heat transfer coefficients (i.e., metals that are good thermal conductors with relatively higher elastic modulus). Because of the relatively lower elastic modulus of thermally conductive solder 124, the thermally conducting solder 124 relatively relaxes under thermal excursions, i.e., when heat is being removed from the operating die. Further, the ability of the thermally conducting solder 124 to relax and/or expand, enables an increased, repeatable, reliable conduction contact with the lateral heatsink 304 portion of the cover 54, compared to other metals (such as Copper) that are good conductors of heat. Therefore, a relatively increased conduction of heat away from the operating die and into cover 54 may be enabled because of the elastic or deformable nature of the thermally conductive solder 124. These other metals that are good thermal conductors (e.g., Copper, etc.) may be less useful in packaged integrated circuit device 400, due to relatively lower coefficient of thermal expansion and the relatively higher elastic modulus. Reliable and repeatable conduction contact between these other types of metals may not be achievable to the inelastic or stiff nature of these other metals that are good thermal conductors.

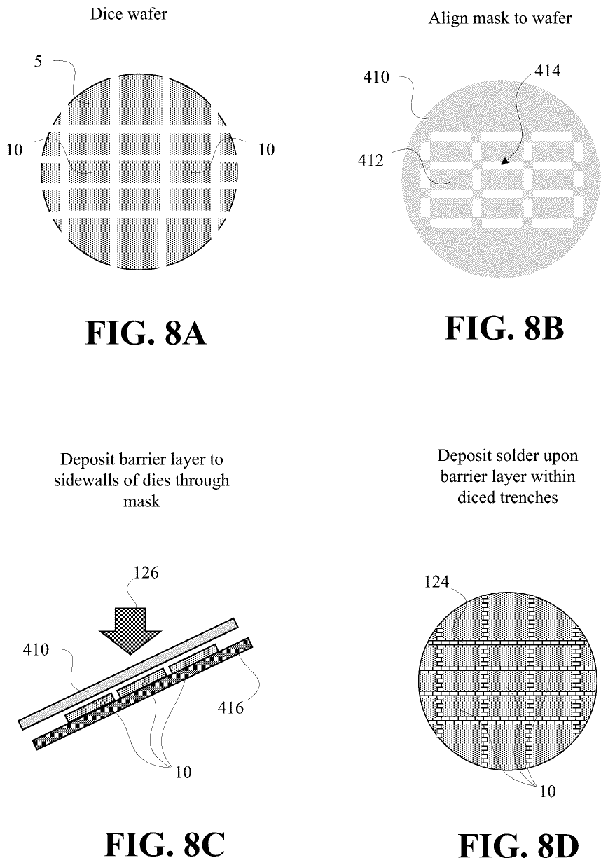

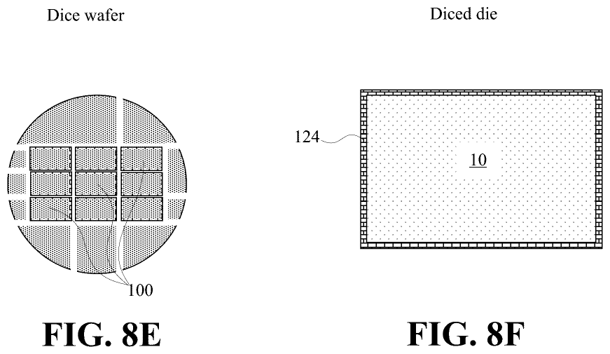

FIG. 8A through FIG. 8F depict a method of fabricating the die with a perimeter of thermally conducting solder 125, according to one or more embodiments of the disclosure. The method includes dicing wafer 5, as depicted in FIG. 8A. Wafer 5 dicing is the process by which the die(s) are separated from the wafer 5 following the processing of the wafer 5. The dicing process can involve scribing and breaking, mechanical sawing, laser cutting, or the like. During dicing, wafers 5 are typically mounted on dicing tape 415, as depicted in FIG. 8C, which has a sticky backing that holds the wafer 5 on a thin sheet metal frame, or the like.

The method may include aligning a mask 410 and/or applying the aligned mask 410 upon the wafer 5, as depicted in FIG. 8B. The mask 410 has masking regions 412 that are configured to align with the die(s) and openings 414 that are configured to align with and generally expose the underlying sidewalls of the die(s).

The method may include applying barrier layer 126 upon the sidewall(s) of the die(s) through the mask 410, as depicted in FIG. 8C. The masking regions 412 of mask 410 may generally block the barrier layer 126 material from being applied to the top or exposed surface of the die(s). The openings 414 of mask 410 may generally allow the barrier layer 126 material to be deposited through the mask 410 and upon the exposed and underlying sidewall(s) of the die(s). For example, the barrier layer 126 may be formed upon sidewalls of the active region 10 (if perimeter region 20 is removed by the initial dicing of the wafer 5), perimeter region 20 (if a portion of the perimeter region 20 is retained by the initial dicing of the wafer), or the like.

The method may continue with depositing thermally conducting solder 124 upon the barrier layer 126, as depicted in FIG. 8D. The thermally conducting solder 124 may be formed to a thickness to generally fill openings or trenches that were formed by the dicing of the wafer 5.

The method may continue with re-dicing wafer 5 and retaining a perimeter of thermal conductive solder 124 upon the sidewall(s) of the diced die(s), as depicted in FIG. 8E. The method may continue with extracting the re-diced die(s) that include the perimeter of thermally conductive solder 124, as depicted in FIG. 8F. The re-diced die(s) may be extracted by die-handling equipment, such as a die bonder or die sorter, further in a packaged integrated circuit device assembly process.

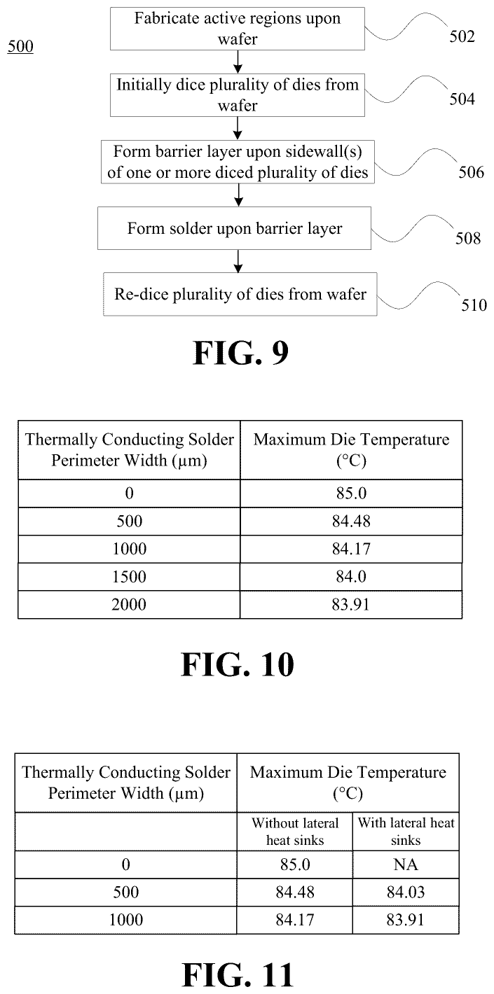

FIG. 9 depicts method 500 of fabricating the die with the perimeter of thermally conducting solder 124, according to one or more embodiments of the disclosure. Method 500 includes fabricating, at block 502, active device regions and/or perimeter device regions 20 upon or within wafer 5. Method 500 may further include, at block 504, initially dicing a plurality of dies from the wafer 5. Method 500 may further include, at block 506, forming barrier layer 126 upon the perimeter sidewall(s) of the respective diced dies. Method 500 may further include, at block 508, forming thermally conducting solder 124 upon the barrier layer 126. The thermally conducting solder 124 may be formed to a thickness to mechanically reconnect or rejoin each of the neighboring plurality of dies. Method 500 may continue, at block 510, with re-dicing the plurality of dies from the wafer 5. The perimeter of thermal conductive solder 124 is retained upon the sidewall(s) of one or more of the plurality of the diced die(s).

FIG. 10 depicts a table characterizing reduction in maximum die temperature as a function of a width of the perimeter of thermally conducting solder 124 surrounding the die, according to an embodiment of the disclosure.

FIG. 11 depicts a table characterizing reduction in maximum die temperature as a function a presence of lateral heatsink(s) 304 that are thermally connected to the perimeter of thermally conducting solder 124 that surrounds the die, according to an embodiment of the disclosure.

Semiconductor devices and methods for forming the same in accordance with the above-described techniques can be employed in various applications, hardware, and/or electronic systems. Suitable hardware and systems for implementing embodiments of the disclosure may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the disclosure. Given the teachings provided herein, one of ordinary skill in the art will be able to contemplate other implementations and applications of embodiments of the disclosure.

In some embodiments, the above-described techniques are used in connection with semiconductor devices that may require or otherwise utilize, for example, complementary metal-oxide-semiconductors (CMOSs), metal-oxide-semiconductor field-effect transistors (MOSFETs), and/or fin field-effect transistors (FinFETs). By way of non-limiting example, the semiconductor devices can include, but are not limited to CMOS, MOSFET, and FinFET devices, and/or semiconductor devices that use CMOS, MOSFET, and/or FinFET technology.

In some embodiments, a semiconductor integrated circuit device includes the FEOL region 103, the first BEOL region 101 coupled to a first side of the FEOL-region 103, the second BEOL region 105 coupled to the second side of the FEOL-region 103, and thermally conducting solder 124 at least partially surrounding a perimeter of the FEOL region 103, the first BEOL region 101, and the second BEOL region 105.

The BEOL region 105 may provide signal routing for one or more active devices in the FEOL region 103, and the BEOL region 101 may provide a power delivery structure for the one or more active devices in the FEOL region 103. The BEOL region 105 may be coupled to the topside heatsink 122, and the BEOL region 101 may be coupled to packaging substrate 102, carrier 52, or the like. The semiconductor integrated circuit device may further include one or more lateral heatsink(s) 304 upon respective sidewalls or side surfaces of the thermally conducting solder 124.

The thermally conducting solder region may include a diffusion barrier layer 126 between (i) the thermally conducting solder 124 and (ii) the FEOL region 103, the BEOL region 101, and the second BEOL region 105. The thermally conducting solder region may further include the oxide layer 124 between the thermally conducting solder 124 and the FEOL region 103. The thermally conducting region may further include an oxide layer between (i) the thermally conducting solder and (ii) the FEOL region 103, the BEOL region 101, and the second BEOL region 105. The thermally conducting solder region may enable heat extraction from lateral or side surfaces of the die, or the like. The thermally conducting solder region may have a width of 50 um or more and may therefore increase the diameter or horizontal dimension(s) of a nominal die by 100 um or more.

The various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A packaged semiconductor integrated circuit device comprising:
a die comprising a first back-end-of-line region coupled to a first side of a front-end-of-line region, a second back-end-of-line region coupled to a second side of the front-end-of-line region, and a thermally conducting solder at least partially surrounding perimeter sidewalls of the front-end-of-line region, the first back-end-of-line region, and the second back-end-of-line region; and
a cover that conceals the die, the cover comprising a lateral heatsink portion in conduction connection with a sidewall of the thermally conducting solder.

2. The packaged semiconductor integrated circuit device of claim 1, wherein the first back-end-of-line region provides signal routing for one or more active devices in the front-end-of-line region, and wherein the second back-end-of-line region provides a power delivery structure for the one or more active devices in the front-end-of-line region.

3. The packaged semiconductor integrated circuit device of claim 2, further comprising:
a carrier; and
a plurality of solder balls that connect the carrier and the second back-end-of-line region.

4. The packaged semiconductor integrated circuit device of claim 3, wherein a reflow temperature of the thermally conducting solder is higher than a reflow temperature of the plurality of solder balls.

5. The packaged semiconductor integrated circuit device of claim 4, further comprising an oxide layer between the thermally conducting solder and the front-end-of-line region.

6. The packaged semiconductor integrated circuit device of claim 5, further comprising an oxide layer between (i) the thermally conducting material and (ii) the front-end-of-line region, the first back-end-of-line region, and the second back-end-of-line region.

7. The packaged semiconductor integrated circuit device of claim 1, wherein the lateral heatsink portion is in direct conduction connection with the sidewall of the thermally conducting solder.

8. The packaged semiconductor integrated circuit device of claim 1, wherein a thermal interface material is between the lateral heatsink portion and the sidewall of the thermally conducting solder.

9. The packaged semiconductor integrated circuit device of claim 1, wherein a width of the thermally conducting solder is 50 um or more.

10. A semiconductor integrated circuit device fabrication method comprising:
initially dicing a plurality of dies from a wafer;
aligning a mask with the wafer;
depositing a barrier layer material through the mask upon perimeter sidewalls of each of the plurality of dies;
depositing thermally conductive solder upon the barrier layer to rejoin the plurality of dies; and
re-dicing the plurality of dies while retaining the thermally conductive solder upon respective perimeter sidewalls of each of the plurality of dies.

11. The semiconductor integrated circuit device fabrication method of claim 10, wherein the plurality of dies each comprise:
a first back-end-of-line region coupled to a first side of a front-end-of-line region;
a second back-end-of-line region coupled to a second side of the front-end-of-line region; and
the thermally conducting solder at least partially surrounding perimeter sidewalls of the front-end-of-line region, the first back-end-of-line region, and the second back-end-of-line region.

12. The semiconductor integrated circuit device of claim 11, wherein the first back-end-of-line region provides signal routing for one or more active devices in the front-end-of-line region, and wherein the second back-end-of-line region provides a power delivery structure for the one or more active devices in the front-end-of-line region.

13. The semiconductor integrated circuit device fabrication method of claim 12, further comprising:
connecting, via conduction, a lateral heatsink to a sidewall surface of the thermally conductive solder of one die of the plurality of dies.

14. The semiconductor integrated circuit device fabrication method of claim 4, further comprising:
connecting, via conduction, a topside heatsink to an upper surface of the first back-end-of-line region of one die of the plurality of dies.

15. The semiconductor integrated circuit device fabrication method of claim 14, further comprising:
forming an oxide layer between the thermally conducting material and the front-end-of-line region.

16. The semiconductor integrated circuit device fabrication method of claim 15, further comprising:
forming an oxide layer between (i) the thermally conducting material and (ii) the front-end-of-line region, the first back-end-of-line region and the second back-end-of-line region.

17. The semiconductor integrated circuit device fabrication method of claim 15, wherein connecting the lateral heatsink to the sidewall surface of the thermally conductive solder and connecting the topside heatsink to the upper surface of the first back-end-of-line region comprises:
connecting a cover to the one die of the plurality of dies.

18. The semiconductor integrated circuit device fabrication method of claim 17 further comprising:
applying a thermal interface material between the upper surface of the first back-end-of-line region and the cover and between the sidewall surface of the thermally conductive solder and the cover.

19. A semiconductor integrated circuit device comprising:
a first back-end-of-line region coupled to a first side of a front-end-of-line region;
a second back-end-of-line region coupled to a second side of the front-end-of-line region; and
a thermally conducting solder at least partially surrounding perimeter sidewalls of the front-end-of-line region, the first back-end-of-line region, and the second back-end-of-line region.

20. The semiconductor integrated circuit device of claim 19, wherein the first back-end-of-line region provides signal routing for one or more active devices in the front-end-of-line region, and wherein the second back-end-of-line region provides a power delivery structure for the one or more active devices in the front-end-of-line region.
